(19) United States
(12) Patent Application Publication
(10) Pub. No.: US 2015/0303650 A1
(43) Pub. Date: Oct. 22, 2015

(54) Low Cost Directly Modulated TWDM Burst Mode Laser

(71) Applicant: Alcatel-Lucent USA Inc., Murray Hill, NJ (US)

(72) Inventors: Vincent Etienne Houtsma, New Providence, NJ (US); Doutje T. van Veen, New Providence, NJ (US)

(73) Assignee: ALCATEL-LUCENT USA INC., Murray Hill, NJ (US)

(21) Appl. No.: 14/258,198

(22) Filed: Apr. 22, 2014

(51) Int. Cl. H01S 5/062; H01S 5/042; H01S 5/12

(52) U.S. Cl. CPC H01S 5/062; H01S 5/12; H01S 5/0425

(57) ABSTRACT

A directly modulated multi-electrode DFB laser is used to transmit information in a TWDM environment where the output power and the output wavelength of the laser output signal are determined by the ratios of bias currents simultaneously applied to the electrodes of the laser by a control circuit. The total amount of current applied to the electrodes is kept to a constant value to maintain the temperature of the laser constant. The electrodes of the DFB laser are positioned so as not to experience any thermal coupling between them or with any other component of the DFB laser.

### FIELD OF THE INVENTION

The present invention generally relates to communication networks and specifically to a laser device for transmitting information in burst mode in a communication network.

### BACKGROUND OF THE INVENTION

For various types of communication networks such as TDMA (Time Division Multiple Access) networks, information transmitted over the network is usually in the form of data bursts. Data bursts by their very nature require relatively large bandwidths (albeit for a relatively small period of time, namely the length of the burst) thus necessitating a proper transmitter and receiver that can handle such relatively wide bandwidth data. The bandwidth available for data often dictates the type of signal used to transmit the data and the type of medium through which the data is transmitted.

One type of signal and medium that provide relatively wide bandwidths are optical signals transmitted through optical fibers. In many communication networks optical signals are used in one or more portions of the network requiring the conversion of signals throughout the network from electrical or electronic form to optical signals. These signals are often converted to optical signals and transmitted by a laser in accordance with a data rate or symbol rate. Although transmission of signals in optical form provides greater availability of bandwidth, there are some limitations that complicate the use of lasers or laser devices for transmission of data. The corrective measures necessary for addressing these limitations are often costly and thus reduce the practicability of the use of lasers for transmission of data. To reduce costs, Distributed Feedback (DFB) lasers are sometimes used in communication networks as these lasers are relatively inexpensive.

Directly modulated DFB lasers are sometimes used as transmitters of data wherein the DFB laser bias is switched ON for the transmission of the data and then switched OFF once data transmission is completed. DFB lasers exhibit significant wavelength drift when switched to their ON state due to thermal self heating. For wavelength selective applications such as TWDM (Time and Wavelength Division Multiplexing), the wavelength drift phenomenon is undesirable.

One supposed solution to the wavelength drift problem is to significantly reduce the power of the laser during its ON state to minimize the self-heating that inevitably occurs; this solution, however, is clearly unacceptable on its face. Another supposed solution is to use a coarse wavelength grid so that the wavelength will be within a defined or selected channel during the transmission of the data burst. The problem with this coarse grid approach is that the wavelength grid will be limited in terms of the number of channels that can be defined, especially for TWDM. Further, this approach of a coarse grid will necessarily require that the laser be tuned over a relatively much wider wavelength range to cover all of the available channels for use. Finally, one can use an externally modulated laser to circumvent the self heating problem described above; this approach, which may resolve the self heating problem, requires an expensive external modulator and additional circuitry as compared to the use of the directly modulated DFB laser.

### BRIEF SUMMARY OF THE INVENTION

The present invention provides a multi-electrode directly modulated tunable laser comprising a lasing device having a plurality of electrodes and a control circuit coupled to the electrodes to simultaneously provide a current to each of the electrodes independent of any other current through any of the other electrodes such that a constant total current flows through the electrodes at all times without any thermal coupling between any of the electrodes. The lasing device has an active region and is configured such that each of the currents applied to each of the electrodes causes injection of carriers into the active region and also causes a change in carrier density of separate parts of the active region; these changes are due to the applied currents and/or their ratios and not to any thermal response of the lasing device. As a result, the laser generates an output signal. The output power and the wavelength of the laser output signal can be varied or changed by changing the ratio(s) of the currents applied to the different electrodes. Thus, the current ratios determine the wavelength and output powers of the generated output signal.

In one embodiment, the lasing device is a DFB (Distributed Feedback) laser having two electrodes. Such a laser can be obtained, for example, from a directly modulated DFB laser with one electrode used for the modulation input where the one electrode is reconfigured as two separate and distinct electrodes.

### BRIEF DESCRIPTION OF THE DRAWINGS

FIG. 1 shows a sectional view of a DFB laser embodiment of the device of the present invention.

FIG. 2 shows a perspective view of the lasing device of FIG. 1.

FIG. 3 shows the output wavelength and output power response of the laser of FIG. 1 for certain current ratios.

### DETAILED DESCRIPTION

The present invention provides a multi-electrode directly modulated tunable laser comprising a lasing device having a plurality of electrodes and a control circuit coupled to the electrodes to simultaneously provide a current to each of the electrodes independent of any other current through any of the other electrodes such that a constant total current flows through the electrodes without any thermal coupling between any of the electrodes.

The lasing device has an active region and is configured such that each of the currents applied to each of the electrodes causes injection of carriers (i.e., holes and electrons) into the active region and also causes a change in carrier density of separate parts of the active region; these changes are due to the applied currents and not to any thermal effects of the lasing device. Each of the electrodes is a functioning electrode that is positioned with respect to the other electrodes such that there is no thermal coupling between any of the electrodes. A functioning electrode is an electrode positioned so that current passing through such an electrode results in carriers (i.e., holes and electrons) being injected into the active region of the lasing device and such a current is not the result of any thermal effects or thermal coupling between the electrode and any other electrode or component of the lasing device. As a result, the laser generates an output signal (i.e., an optical signal). The output power and the wavelength of the laser output signal can be varied or changed by changing the ratio(s) of the currents applied to the different electrodes while keeping the total amount of applied current constant. Also, all of the different currents applied to the different electrodes are applied simultaneously. Thus, the ratios of the applied currents determine the wavelengths and power of the laser generated output signal. Hereinafter, the terms “current” and “bias current” will be used interchangeably.

In one embodiment, the lasing device is a DFB (Distributed Feedback) laser with two electrodes. Such a lasing device can be obtained, for example, from a directly modulated DFB laser with one electrode used for the modulation input and where the one electrode is reconfigured as two separate and distinct electrodes properly positioned with respect to each other to cause carriers to be injected into the active region of the lasing device when bias currents are applied to such electrodes. The injection of the carriers is due to currents applied to such electrodes and is not due to any thermal effects and thermal coupling between the electrodes.

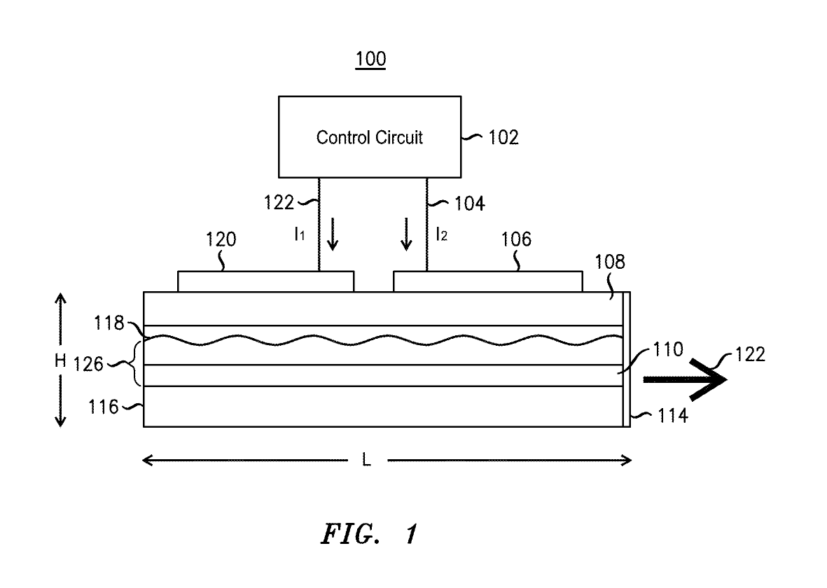

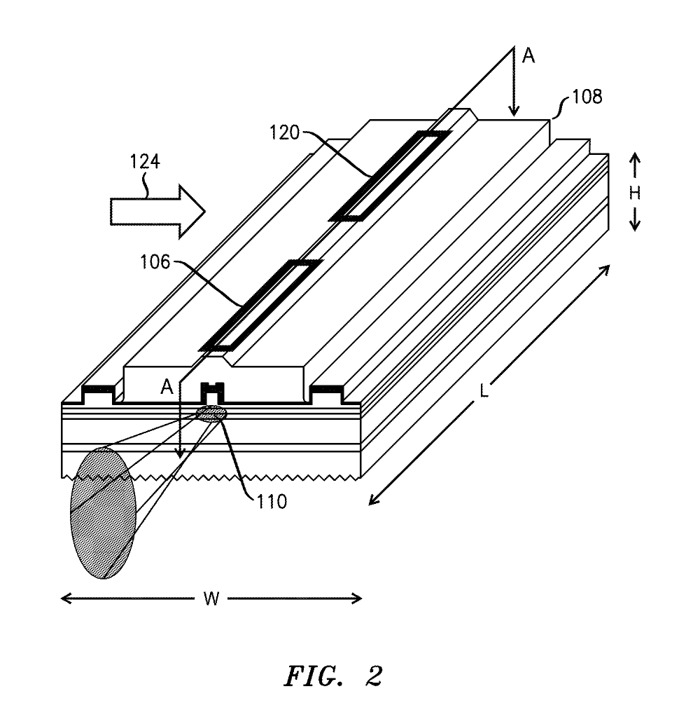

The multi-electrode directly modulated tunable laser of the present invention comprises a lasing device shown in FIG. 2. The lasing device of FIG. 2 has width W, length L and height H as shown. The cross-section of the lasing device of FIG. 2 cut along line A-A and viewed in the direction of arrow 124 is shown in FIG. 1. FIG. 1 also shows a control circuit coupled to the lasing device thus constituting the multi-electrode tunable laser 100 of the present invention. Although the coupling between the control circuit 102 and the lasing device as shown in FIG. 1 is electrical, the coupling may also be electromagnetic, electronic, optical or any other type of coupling that provides for a bias current (preferably a modulated bias current) to pass through each of the electrodes.

Continuing with FIG. 1, the particular embodiment of the laser of the present invention shows a DFB (Distributed Feedback) lasing device electrically coupled to control circuit 102. The coupling between the lasing device and the control circuit 102 is such that bias currents I₁ and I₂ have certain time and amplitude characteristics (discussed infra) to operate the DFB lasing device in a thermally neutral mode.

The thermally neutral mode refers to the negation of self heating typically experienced by a directly modulated laser as the total bias current applied to such a laser is changed or varied. In a thermally neutral mode, the total amount of current applied to the various electrodes of the lasing device is maintained at a constant level (regardless of the change in the ratio of the currents to each other) at all times to keep the temperature of the laser junction constant at all times; that is, once current is applied to the electrodes and total bias current is maintained at a constant level, the temperature of the junction of the lasing device remains relatively constant and neither increases nor decreases by any appreciable or detectable amount. Further, the lasing device is caused to generate a collimated beam of substantially monochromatic light whose wavelength changes in accordance with the ratios of the currents applied to the electrodes of the lasing device. In this manner, switching the ratios of the applied currents causes the lasing device to output light that switches between monochromatic light of different wavelengths in accordance with the switching rate. The power of the generated beam of light is also dependent on the particular current ratios.

Control circuit 102 comprises electrical, electronic and other types of circuitry that provide currents I₁ and I₂ in a well known manner to directly modulate the lasing device. Currents I₁ and I₂ are bias currents which can be modulated and are applied to electrodes 120 and 106 via paths 122 and 104 respectively. In the particular embodiment being discussed, the paths 122 and 104 are conductors which are electrically connected to the electrodes 120 and 106 respectively; such a coupling is an electrical coupling. The bias currents of certain amplitudes are switched ON for certain periods of time consistent with the duration of the burst of data being transmitted. The electrodes 120, 106 are electrically connected and physically mounted onto semiconductor layer 108 which serves as the top electrode of the laser (i.e., P-type semiconductor). A diffraction grating is formed in layer 118 whereby such grating serves as a wavelength selective element.

The lasing device also has a bottom electrode which is formed in bottom layer 116 of semiconductor material (i.e., N-type semiconductor). Top layer 108 and bottom layer 116 form a p-n junction region together with layer 110 and 118 whereby layer 110 becomes an optical cavity from which monochromatic light is emitted and through which such light travels to exit at one end of the lasing device. That is, carriers (i.e., holes and electrons) are caused by the applied currents to enter an active region 126 (region 110 combined with the region below grating 118) and interact with each other giving off photons (i.e., light), which are reflected back by diffraction grating 118 (acting as a mirror) into active region 126. As a result, more holes and electrons are generated and are reflected back into active region 126 such that region 110 becomes an optical cavity or optical path from which monochromatic light is emitted in the direction indicated by arrow 122. Because the electrodes are positioned with respect to each other so as to prevent any thermal coupling between them, the carriers entering the active region are due to the applied currents and not to any thermal effects such as thermal heating of the lasing device. Further, there exist no thermal heating or other thermal effects that would affect the amplitude of the applied currents or cause the applied currents to drift in any manner.

One end (i.e., the end from which light is emitted) of the lasing device is terminated with anti-reflection coating 114 and the opposite end is terminated with high reflectivity material; the light emitted from the active region passes through the anti-reflection coating 114. Thus, both ends in conjunction with diffraction grating 118 promote the capture of light within the p-n junction region to form the optical cavity 110. The amplitude or power of the emitted light depends on the particular ratio(s) of the applied currents.

Also, the wavelength of the emitted monochromatic light is dependent upon the ratios of the applied currents. That is, depending on the ratio(s) of the applied currents, the carrier density distribution inside the active region changes and consequently the emitted wavelength of the active region 126 changes.

In particular, the lasing wavelength is tuned electrically by means of current injection into one section of the device, increasing carrier density in that part, while carrier density in another section is decreased, because the total bias current is kept constant, so that the total gain balances with any losses occurring in the optical cavity. Since switching of the optical wavelength and/or output power is due to a change in carrier injection and not due to the thermal response (i.e. a change in wavelength selection of the grating due to a thermal refractive index change) of the lasing device, the settling time should be relatively short (i.e., fast settling time). Settling time refers to the period of time needed for the output of the laser to stabilize to a particular output power or amplitude at a fixed wavelength. Relatively fast settling times are conducive to proper burst mode operation of the lasing device where the total length of a burst of data (i.e., packet length) can be on the order of 1 micro second.

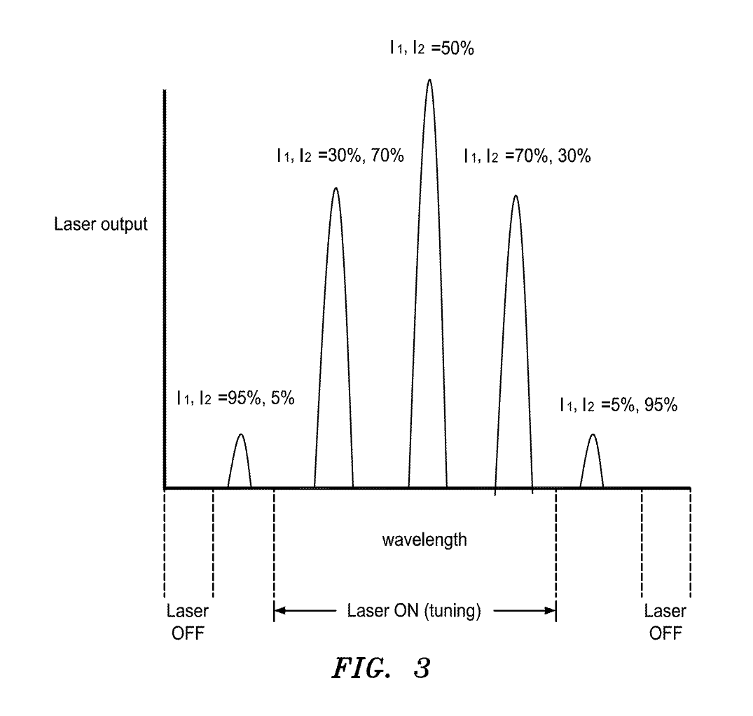

Referring now to FIG. 3, a graph depicting the dependency of wavelength and/or output power on the ratio of the applied currents is shown. The lasing device is preferably controlled so that the bias currents are not turned OFF completely even during times of no operation. In the OFF state, the ratios of the applied currents can be selected such that the output power of the monochromatic light is relatively negligible so that any output optical signal can be easily suppressed by insertion losses in the medium (i.e., fiber optic cable) through which such signal is propagating. Also, additional circuitry and/or devices may be appended to the output of the lasing device to suppress these negligible outputs. Negligible output power can be arbitrarily defined by designers of systems within which the laser of the present invention operates. Thus, even during periods of no activity, currents are still applied to the electrodes of the lasing device of the present invention. Because the lasing device is never switched OFF completely during times of no burst activity and because the currents needed to operate the device at a desired wavelength and output power are applied continuously while maintaining a constant total bias current, the device self-heating stays constant. This means the device is able to quickly react and settle to the sudden transmissions of new bursts of data after a period of inactivity. The ratio of the bias currents with respect to each other can be selected such that they operate the lasing device at two particular wavelengths and one output power as will be shown and discussed below.

In general, a control circuit coupled to all N electrodes of a lasing device (preferably a DFB lasing device) provides different currents (i.e., bias currents) simultaneously to the N electrodes of the lasing device to operate the device at one or more desired output power and wavelength(s) where N is an integer equal to 2 or greater. In the discussion above, N=2; however in some applications it can be readily envisioned where N=3 or greater for operation of the lasing device at one or more output power and/or at one or more output wavelength. The ratio(s) of the applied currents can be selected such that the lasing device is operated at certain wavelengths and one output power for all wavelengths. For example, for N=2, the ratios can be complementary of each other so that the wavelengths are different but because of the complementary nature of the current ratios, the output power for both wavelengths are the same. For example, as shown in FIG. 3, a first current I₁=0.31 and a second current I₂=0.71 for one wavelength and for the other wavelength I₁=0.71 and I₂=0.31, the output power for both wavelengths are the same; I is the total current. In general for I₁=k₁I and I₂=k₂I where k₁+k₂=1, (k₁, k₂ are real numbers) a first wavelength is generated, and where I₁=k₂I and I₂=k₁I a second wavelength is generated where both wavelengths have the same output power because of the complementary nature of the ratios. The complementary nature of the bias currents refers to the sum of the applied individual bias currents equal to the same constant value as the values of the individual bias currents are varied.

While various aspects of the present invention have been described above, it should be understood that they have been presented by way of example and not by limitation. It will be apparent to persons skilled in the relevant art(s) the various changes in form and detail can be made therein without departing from the spirit and scope of the present invention. Thus, the present invention should not be limited by any of the above described exemplary aspects, but should be defined only in accordance with the following claims and their equivalents.

In addition it should be understood that the DFB embodiment discussed above in no way limits the multi-electrode tunable laser to certain classes or types of lasers or lasing devices. It will be readily understood that the present invention, and more particularly its claims, describe any lasing device (whether constructed with semiconductor material or not) with a control circuit that can be used for transmission of information in a burst mode based on ratios of currents applied simultaneously to the various electrodes of the lasing device.

1. A multi-electrode tunable laser comprising:
a lasing device having a plurality of electrodes; and
a control circuit coupled to the electrodes to simultaneously apply a varied bias current to each of said electrodes such that a constant total bias current flows through the electrodes to cause the lasing device to generate output signals for transmission at one or more wavelengths and output powers where said wavelengths and said output powers are determined by one or more ratios of the applied bias currents and where the plurality of electrodes are not thermally coupled to each other.

2. The multi-electrode tunable laser of claim 1 where the bias currents are applied to the lasing device even during periods of no signal transmission.

3. The multi-electrode tunable laser of claim 1 where the control circuit is electrically coupled to the electrodes of the lasing device.

4. The multi-electrode tunable laser of claim 1 where the electrodes are positioned with respect to each other so that there is no thermal coupling between any of the electrodes.

5. The multi-electrode tunable laser of claim 1 where the lasing device is a distributed feedback lasing device.

6. The multi-electrode tunable laser of claim 1 where the applied currents are modulated bias currents.

7. The multi-electrode tunable laser of claim 1 where the lasing device has two electrodes.

8. The multi-electrode tunable laser of claim 7 where the control circuit switches the lasing device between two output wavelengths of equal output power.

9. The multi-electrode tunable laser of claim 8 where a first bias current applied to a first electrode is equal to k₁I and a second bias current applied to a second electrode is equal to k₂I where k₁+k2=1 where I is the total constant bias current and k₂, and I are real numbers and said first and second applied bias currents cause a first output wavelength with a first output power, and
where the first current is applied to the second electrode and the second current is applied to the first electrode to cause a second output wavelength having a second output power equal to the first output power.

10. The multi-electrode tunable laser of claim 1 where the lasing device has more than two electrodes.

11. The multi-electrode tunable laser of claim 1 where the lasing device is a directly modulated DFB laser with one electrode reconfigured as two separate and distinct electrodes.

12. The multi-electrode tunable laser of claim 1 where the lasing device has N electrodes and the applied bias currents are complementary to each other where N is an integer equal to 2 or greater.
